(19) United States
(12) Patent Application Publication
(10) Pub. No.: US 2012/0018723 A1
(43) Pub. Date: Jan. 26, 2012

(54) STRUCTURE AND METHOD FOR TESTING THROUGH-SILICON VIA (TSV)

(76) Inventors: Keng-Li SU, Hsinchu City (TW); Chih-Sheng Lin, Tainan County (TW); Wen-Pin Lin, Changhua County (TW); John H. Lau, Taipei City (TW)

(21) Appl. No.: 12/967,932

(22) Filed: Dec. 14, 2010

(30) Foreign Application Priority Data
Jul. 20, 2010 (TW) 099123752

(51) Int. Cl. H01L 23/58; H01L 21/66

(52) U.S. Cl. 257/48; 438/18; 257/E23.002; 257/E21.531

(57) ABSTRACT

A test structure including at least one ground pad, an input pad, at least one first through-silicon via (TSV), at least one second TSV and an output pad is disclosed. The ground pad receives a ground signal during a test mode. The input pad receives a test signal during the test mode. The first TSV is coupled to the input pad. The output pad is coupled to the second TSV. No connection line occurs between the first and the second TSVs. During the test mode, a test result is obtained according to the signal of at least one of the first and the second TSVs, and structural characteristics can be obtained according to the test result.

### CROSS REFERENCE TO RELATED APPLICATIONS

This Application claims priority of Taiwan Patent Application No. 99123752, filed on Jul. 20, 2010, the entirety of which is incorporated by reference herein.

### BACKGROUND

1. Technical Field

The disclosure relates to a test structure which is capable of obtaining whether a through-silicon via (TSV) within a 3D IC is normal.

2. Description of the Related Art

With technological development, a multitude of chips may now be integrated into a signal package. Thus, the gate length of a current MOS has become shorter, and the speed of the signal in the current MOS has become faster.

For deep submicron meter generation, circuit efficiency is influenced by RC delay, which is related to the length of connection lines. Currently, the length of connection lines can be reduced by a 3D connection method, and the RC delay is reduced and the circuit efficiency is increased.

In a signal package, the connection between chips therein utilizes through-silicon vias (TSVs). However, a tester hardly tests whether the TSVs are normal because the filler depth of the TSV is very deep.

### SUMMARY

In accordance with an embodiment, a test structure comprises at least one ground pad, an input pad, at least one first through-silicon via (TSV), at least one second TSV and an output pad. The ground pad receives a ground signal during a test mode. The input pad receives a test signal during the test mode. The first TSV is coupled to the input pad. The output pad is coupled to the second TSV. No connection line occurs between the first and the second TSVs. During the test mode, a test result is obtained according to the signal of at least one of the first and the second TSVs, and structural characteristics can be obtained according to the test result.

A test method for a test structure is provided. When the test structure is produced by a TSV procedure, at least one first TSV and at least one second TSV are formed in the test structure. An exemplary embodiment of a test method is described in the following. A test signal is provided to the first TSV. The signal of at least one of the first and the second TSVs is measured to obtain a test result. The characteristic of the first and the second TSVs is obtained according to the test result. When a DC signal is provided to the first TSV, the DC signal cannot be measured from the second TSV.

A detailed description is given in the following embodiments with reference to the accompanying drawings.

### BRIEF DESCRIPTION OF THE DRAWINGS

The disclosure can be more fully understood by referring to the following detailed description and examples with references made to the accompanying drawings, wherein:

FIG. 1A is a schematic diagram of an exemplary embodiment of a test structure;

FIG. 1B is a top-view diagram of an exemplary embodiment of the test structure shown in FIG. 1A;

FIG. 2 is an equivalent circuit of an exemplary embodiment of the test structure;

FIG. 3A is a schematic diagram of another exemplary embodiment of a test structure;

FIG. 3B is a top-view diagram of an exemplary embodiment of the test structure shown in FIG. 3A;

FIGS. 4A˜4D are arrangement diagrams of other exemplary embodiments of the TSVs;

FIG. 5 is a schematic diagram of an exemplary embodiment of a wafer; and

FIG. 6 is a schematic diagram of an exemplary embodiment of a test method.

### DETAILED DESCRIPTION OF THE DISCLOSURE

The following description is a mode of carrying out the disclosure. This description is made for the purpose of illustrating the general principles of the disclosure and should not be taken in a limiting sense. The scope of the disclosure is determined by reference to the appended claims.

A test signal is provided to a test structure comprising at least two TSVs. A coupling effect is caused between the at least two TSVs. It is determined whether the at least two TSVs are normal according to the variation amount of the coupling effect and a variation amount of an impedance characteristic of a parasitic RLC parameter. The impedance characteristic of the parasitic RLC parameter is obtained according to the coupling effect.

Furthermore, before thinning a wafer, if the TSVs within the wafer are measured and the TSVs are abnormal, the following procedures (e.g. package procedures) can be immediately stopped. Thus, the yield of the wafer can be increased, the manufacturing cost can be reduced, and the following procedures and stacking package procedures are stopped.

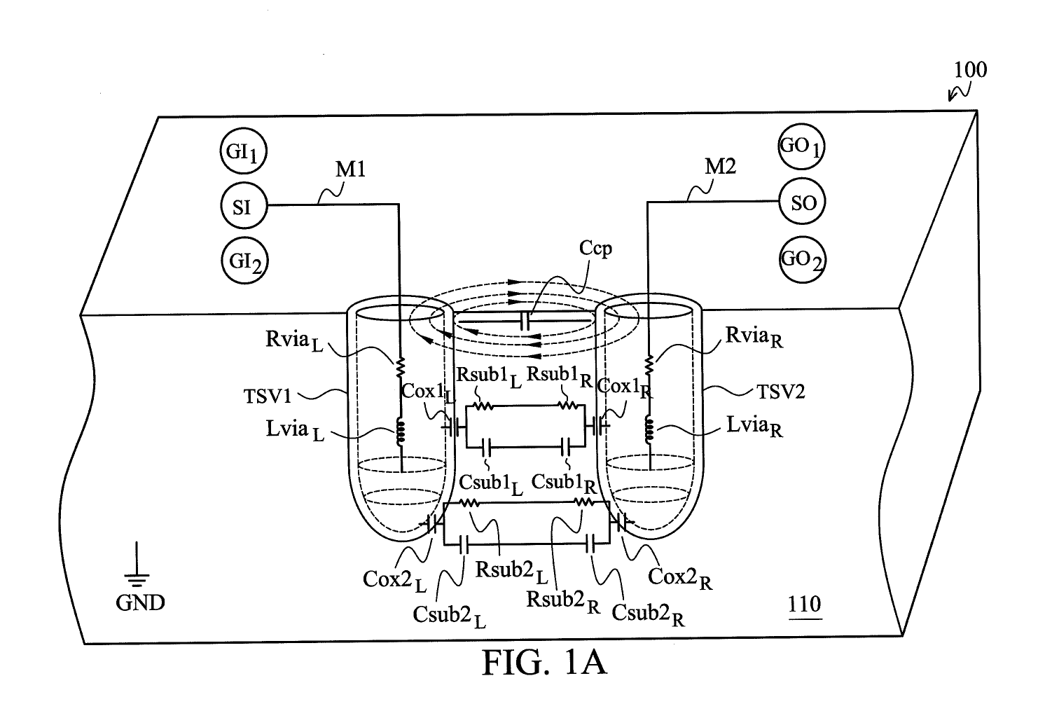

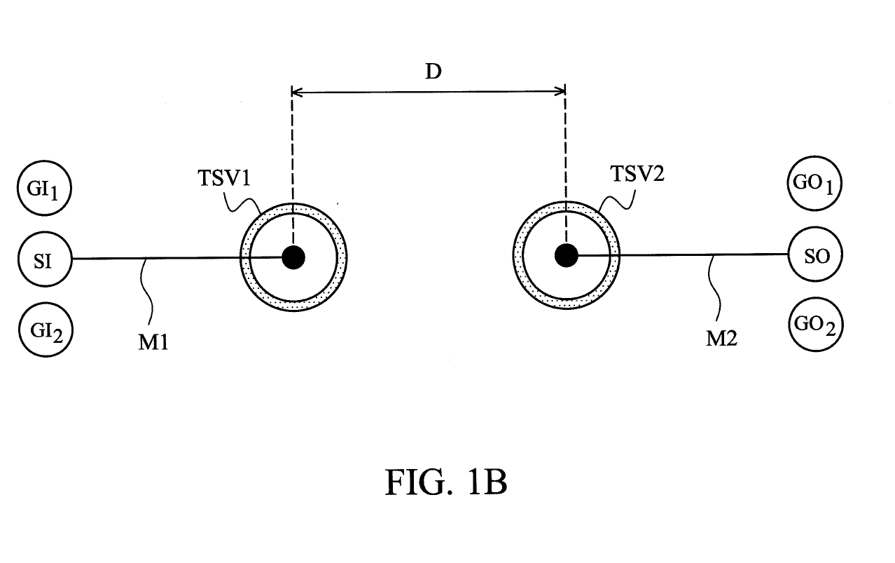

FIG. 1A is a schematic diagram of an exemplary embodiment of a test structure. The test structure 100 comprises at least one ground pad, an input pad SI, through-silicon vias TSV1, TSV2 and an output pad SO. In one embodiment, the test structure 100 is formed in a wafer.

In this embodiment, the test structure 100 comprises ground pads GI₁, GI₂, GO₁ and GO₂. During a test mode, at least one of the ground pads GI₁, GI₂, GO₁ and GO₂ receives a ground signal GND. The disclosure does not limit the number of ground pads used. In one embodiment, the test structure 100 may comprise a single ground pad approaching the input pad SI or the output pad SO. In another embodiment, the single ground pad may be disposed between the input pad SI and the output pad SO. In another embodiment, the test structure 100 comprises two ground pads. One of the two ground pads approaches the input pad SI and another ground pad approaches the output pad SO. In other embodiments, the test structure 100 comprises three or more ground pads.

Additionally, the disclosure does not limit the location of the ground pads GI₁, GI₂, GO₁ and GO₂. In one embodiment, the ground pads GI₁, GI₂, GO₁ and GO₂ are divided into a first group and a second group. The first group comprises the ground pads GI₁ and GI₂. The second group comprises the ground pads GO₁ and GO₂. The distance between a first group pad of the first group and the through-silicon via TSV1 is shorter than the distance between the first group pad and the through-silicon via TSV2. The distance between a second group pad of the second group and the through-silicon via TSV2 is shorter than the distance between the second group pad and the through-silicon via TSV1. In this embodiment, the ground pads GI₁ and GI₂ approach the input pad SI. The input pad SI is disposed between the ground pads GI₁ and GI₂. The ground pads GO₁ and GO₂ approach the output pad SO. The output pad SO is disposed between the ground pads GO₁ and GO₂.

During the test mode, the input pad SI receives a test signal. The disclosure does not limit the type of the test signal. In this embodiment, the test signal only comprises an alternating current (AC) component. In other embodiments, the test signal comprises a direct current (DC) component and an AC component. The disclosure does not limit the frequency of the AC component and the level of the DC component. Any signal can serve as the test signal, as long as the signal is capable of causing a coupling effect between the through-silicon via TSV1 and TSV2.

The through-silicon via TSV1 is coupled to the input pad SI. The through-silicon via TSV2 is coupled to the output pad SO. In this embodiment, no connection line is between the through-silicon via TSV1 and TSV2. Thus, when a DC signal is provided to the through-silicon via TSV1 and then the through-silicon via TSV2 is measured, no signal can be obtained in the through-silicon via TSV2 because the DC signal cannot cause a coupling effect between the through-silicon vias TSV1 and TSV2. Thus, the state between the through-silicon vias TSV1 and TSV2 is referred to open.

During the test mode, the input pad SI receives a test signal. Since the test signal causes a coupling effect between the through-silicon vias TSV1 and TSV2, when at least one of the through-silicon vias TSV1 and TSV2 is measured, a test result can be obtained. The test result relates to an impedance of a parasitic equivalent RLC. The characteristic of the through-silicon vias TSV1 and TSV2 can be obtained according to the test result.

In one embodiment, an S-parameter measuring method, a Y-parameter measuring method or a Z-parameter measuring method is employed to measure at least one of the through-silicon vias TSV1 and TSV2. In other embodiments, a GSG test probe with high frequency is utilized to measure at least one of the through-silicon vias TSV1 and TSV2 to obtain a test result relating to an impedance of a parasitic equivalent RLC of the through-silicon vias TSV1 and TSV2.

If a TSV manufacturing procedure is unstable, or the through-silicon vias TSV1 and TSV2 are unhealthy, such as a broken side wall, a thinned side wall or a thick side wall, the coupling effect between the through-silicon vias TSV1 and TSV2 and the impedance of the parasitic equivalent RLC are changed. Thus, the manufacturing result of the through-silicon vias TSV1 and TSV2 can be monitored according to the signal of at least one of the through-silicon vias TSV1 and TSV2.

FIG. 1B is a top-view diagram of an exemplary embodiment of the test structure shown in FIG. 1A. A connection line M1 is electrically connected between the through-silicon via TSV1 and the input pad SI. A connection line M2 is electrically connected between the through-silicon via TSV2 and the output pad SO. The disclosure does not limit the type of the connection lines M1 and M2. In one embodiment, the connection line is a conductor or a semiconductor.

Additionally, a distance D occurs between the through-silicon vias TSV1 and TSV2. The disclosure does not limit the length of the distance D. In one embodiment, the distance D is less than a value. The value may equal to the diameter of one of the through-silicon vias TSV1 and TSV2 multiplied by 10, but the disclosure is not limited thereto. In other embodiments, if the strength of the test signal is strong enough, the distance D can exceed the value. Further, if the number of the through-silicon vias is enough, the distance D can exceed the value.

In addition, the disclosure does not limit the surface shapes of the through-silicon vias TSV1 and TSV2. In this embodiment, the surface shapes of the through-silicon vias TSV1 and TSV2 are circular. In another embodiment, the surface shapes of the through-silicon vias TSV1 and TSV2 are different. In some embodiments, the surface shapes of the through-silicon vias TSV1 and TSV2 are rectangular or other shapes.

Similarly, the disclosure does not limit the surface shapes of the input pad SI, the output pad SO and the ground pads GI₁, GI₂, GO₁ and GO₂. In this embodiment, the surface shapes of the input pad SI, the output pad SO and the ground pads GI₁, GI₂, GO₁ and GO₂ are the same as the surface shapes of the through-silicon vias TSV1 and TSV2.

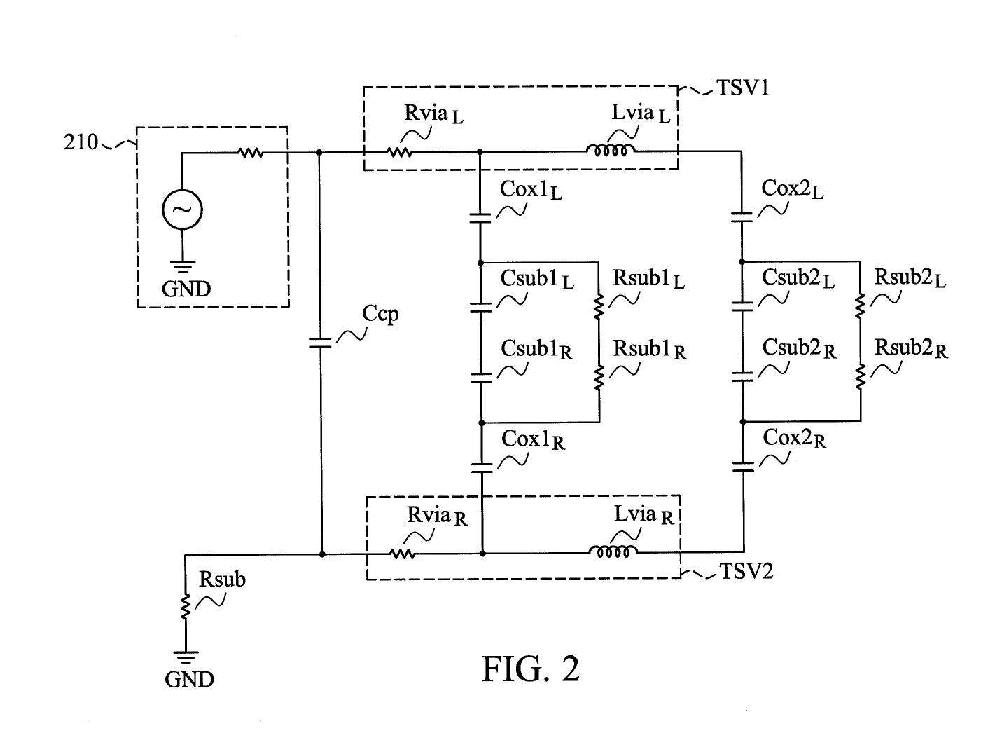

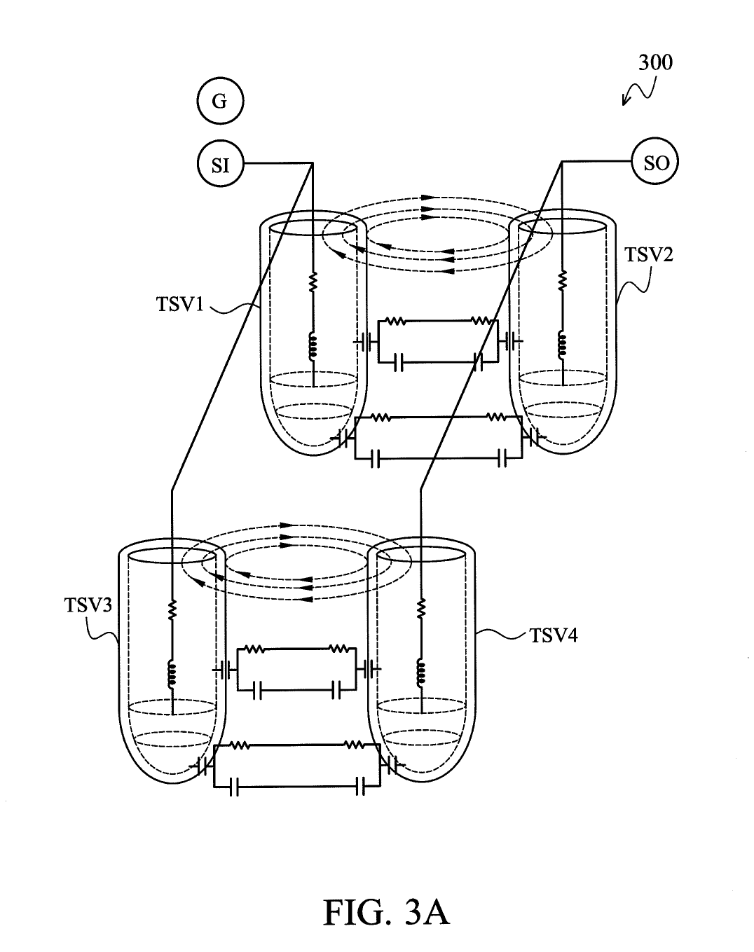

FIG. 2 is an equivalent circuit of an exemplary embodiment of the test structure. A resistor Rvia_{L}, and an inductor Lvia_{L}, correspond to the through-silicon via TSV1. The resistor Rvia_{L} is serially connected to the inductor Lvia_{L}. Similarly, a resistor Rvia_{R} and an inductor Lvia_{R} correspond to the through-silicon via TSV2. The resistor Rvia_{R} is serially connected to the inductor Lvia_{R}. When a test signal is provided to the input pad SI, a coupling effect is caused between the through-silicon vias TSV1 and TSV2. FIG. 2 can represent the equivalent circuit of the test structure 100.

The symbol 210 is an impedance of a test apparatus, which is utilized to provide the test signal. The capacitor Ccp is a coupling capacitor between the through-silicon vias TSV1 and TSV2. Capacitors Cox1_{L} and Cox2_{L} are equivalent capacitors of the oxide (e.g. side wall) of the through-silicon via TSV1. Capacitors Csub1_{L}, and Csub2_{L} are equivalent capacitors formed between a dielectric layer of the through-silicon via TSV1 and the substructure 110. Resistors Rsub1_{L} and Rsub2_{L}, Rsub1_{R} and Rsub2_{R} are equivalent resistors of the substructure 110. Capacitors Cox1_{R} and Cox2_{R} are equivalent capacitors of the oxide (e.g. side wall) of the through-silicon via TSV2. Capacitors Csub1_{R} and Csub2_{R} are equivalent capacitors formed between the dielectric layer of the through-silicon via TSV2 and the substructure 110.

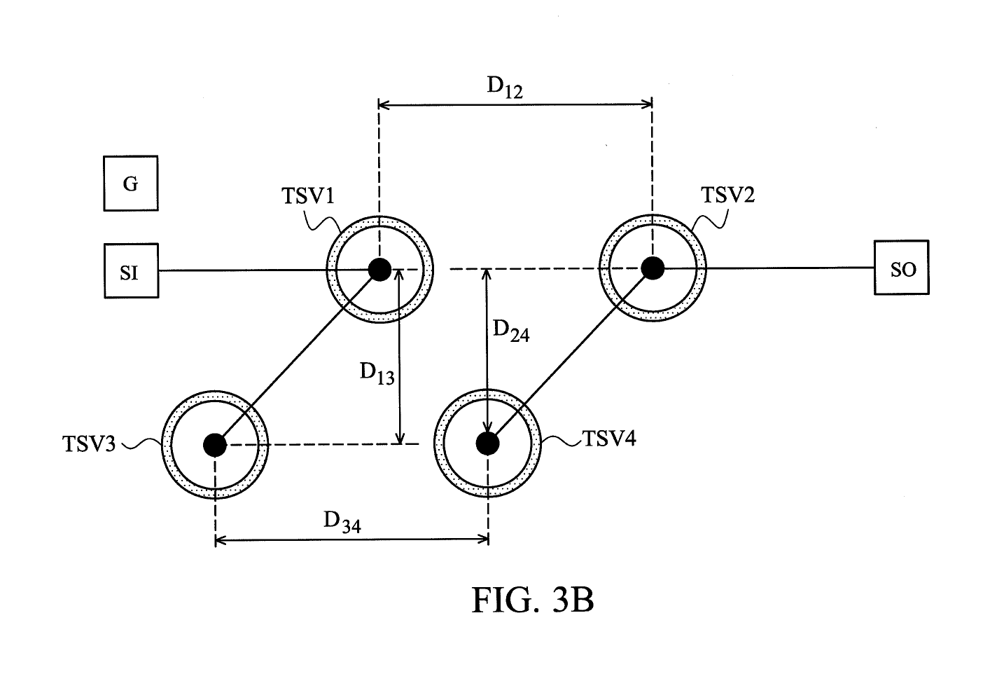

FIG. 3A is a schematic diagram of another exemplary embodiment of a test structure. The test structure 300 comprises a ground pad G, an input pad SI, an output pad SO and through-silicon vias TSV1˜TSV4. FIG. 3A only shows one ground pad G, but the disclosure is not limited thereto. In some embodiments, the number of ground pads G is numerous.

Furthermore, the disclosure does not limit the number of the TSVs. In this embodiment, the test structure 300 comprises four TSVs. The input pad SI is electrically connected to the through-silicon vias TSV1 and TSV3 via a connection line. The output pad SO is electrically connected to the through-silicon vias TSV2 and TSV4 via another connection line.

When the input pad SI receives a test signal comprising an AC component, a coupling effect is caused between the through-silicon vias TSV1 and TSV2 and another coupling effect is caused between the through-silicon vias TSV3 and TSV4. Thus, the characteristics of the through-silicon vias TSV1˜TSV4 can be obtained according to the signal of at least one of the input pad SI and the output pad SO. In other embodiments, if a test signal, that only comprises a DC component and does not comprise an AC component, is provided to the input pad SI, the state of the through-silicon vias TSV1 and TSV2 is referred to as open.

FIG. 3B is a top-view diagram of an exemplary embodiment of the test structure shown in FIG. 3A. In this embodiment, the surface shapes of the ground pad G, the input pad SI and the output pad SO are different from the surface shapes of the through-silicon vias TSV1˜TSV4. In other embodiments, the surface shapes of the through-silicon vias TSV1˜TSV4 are rectangular.

For clarity, FIG. 3B only shows a connection relationship between the through-silicon via TSV1 and the through-silicon vias TSV2˜4. As shown in FIG. 3B, a distance D₁₂ occurs between the through-silicon vias TSV1 and TSV2. A distance D₁₃ occurs between the through-silicon vias TSV1 and TSV3. A distance D₂₄ occurs between the through-silicon vias TSV2 and TSV4. A distance D₃₄ occurs between the through-silicon vias TSV3 and TSV4. In one embodiment, the distances D₁₂, D₁₃, D₂₄ and D₃₄ are the same. In other embodiments, one of the distances D₁₂, D₁₃, D₂₄ and D₃₄ is different from the other distances.

The disclosure does not limit the distance between one TSV and the other TSVs. Additionally, the length of the distance between two TSVs relates to the strength of the test signal and/or the number of the TSVs.

For example, if the strength of the test signal is strong enough, the length of the distance can be set to as being longer. If the strength of the test signal is weak, the length of the distance should be set to as being shorter.

Additionally, assuming a first test structure comprises four TSVs and a second test structure comprises eight TSVs. If a test signal is provided to the first and the second test structures, the distance between the four TSVs is set to be shorter than the distance between the eight TSVs.

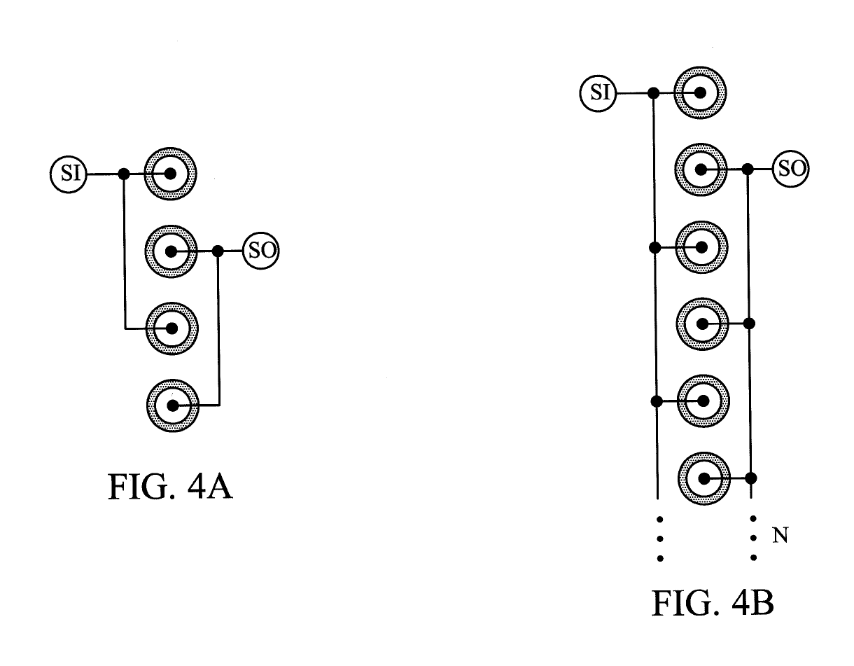

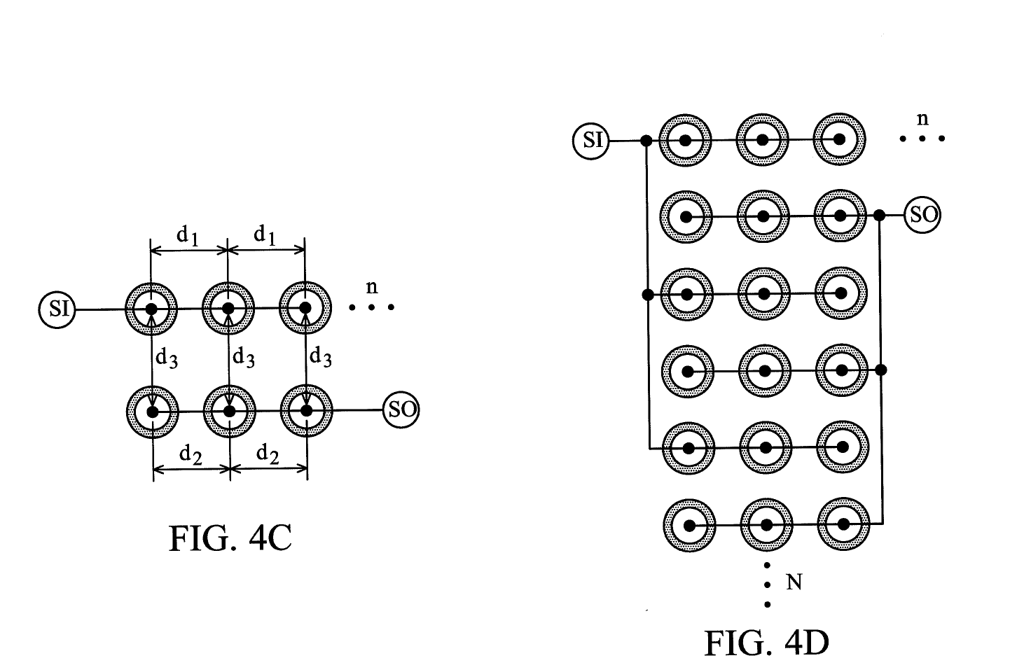

FIGS. 4A˜4D are schematic diagrams of other exemplary embodiments of the arrangement of the TSV. In this embodiment, the TSVs connected to the input pad SI are referred to as first TSVs and the TSVs connected to the output pad SO are referred to as second TSVs.

In FIGS. 4A, 4B and 4D, the first TSVs and the second TSVs are arranged according to an interdigitated method. In FIG. 4C, the first and the second TSVs are parallel and the first TSVs substantially align the second TSVs. In this embodiment, a first distance d₁ occurs between one first TSV and one successive first TSV. A second distance d₂ occurs between one second TSV and one successive second TSV. A third distance d₃ occurs between one first TSV and one second TSV neighboring the first TSV.

In one embodiment, the first distance d₁, the second distance d₂ and the third distance d₃ are the same. In another embodiment, one of the first distance d₁, the second distance d₂ and the third distance d₃ is different from at least one of any two distances. For example, the first distance d₁ may be different from at least one of the second distance d₂ and the third distance d₃. In other embodiments, one of the first distance d₁, the second distance d₂ and the third distance d₃ is less than a value. The value equals to the diameter of one of the first and the second TSVs multiplied by 10. Note that the disclosure does not limit the number of the first and the second TSVs. In one embodiment, the number of the first TSVs is the same as the number of the second TSVs.

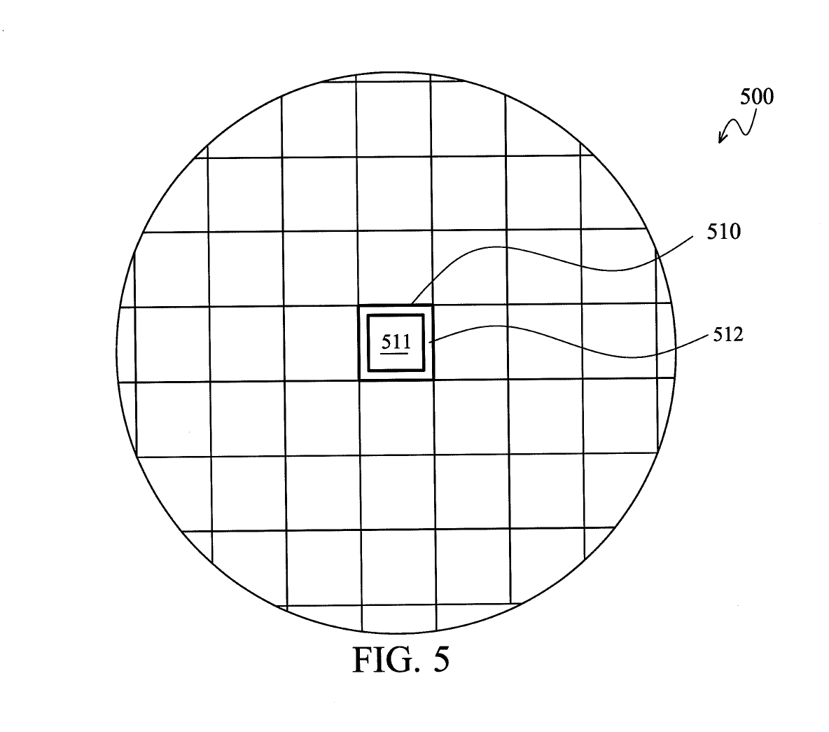

FIG. 5 is a schematic diagram of an exemplary embodiment of a wafer. The wafer 500 comprises a multitude of chips. Taking the chip 510 as an example, the chip 510 comprises an internal circuit 511 and a test structure 512.

The internal circuit 511 comprises a 3D integrated circuit (IC) with a multitude of TSVs. To measure the TSVs within the 3D IC, a multitude of TSVs are formed in the test structure 512 during a TSV procedure. After measuring the TSVs within the test structure 512, it can be determined whether the TSVs within the 3D IC are normal.

The operation of the test structure 512 is similar to the test structures 100 or 300; as such, the description of the test structure 512 is omitted for brevity. In this embodiment, the ground pad, the input pad, the output pad and the TSVs are disposed around the internal circuit 511. After measuring the TSVs within the test structure 512, it can be determined whether the TSVs within the internal circuit 511 are normal.

The disclosure does not limit the time of measuring the TSVs. In one embodiment, the TSVs within the test structure 512 are measured after the wafer 500 has been thinned. At this time, the TSVs pass through the wafer 500. In another embodiment, the TSVs within the test structure 512 are measured before the wafer 500 has been thinned.

Therefore, if the manufacturing procedure of the TSVs is unstable or the TSVs within the test structure 512 are abnormal, following manufacturing procedures are not implemented and manufacturing costs are reduced. When the wafer 500 has not been thinned, the TSV does not pass through the wafer 500.

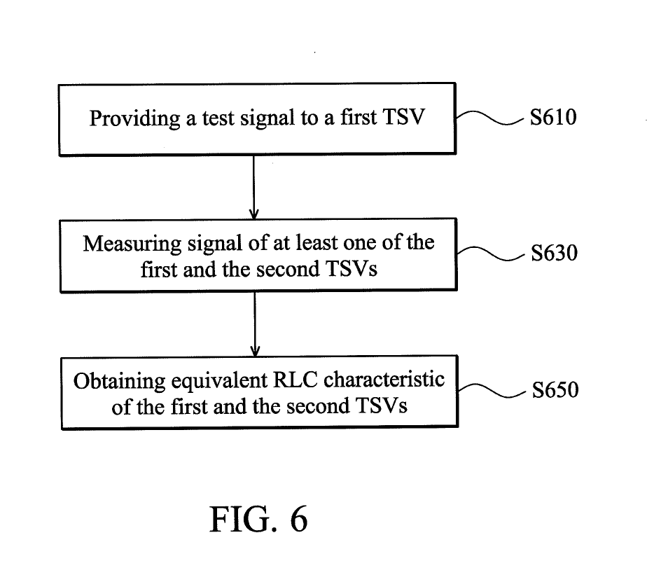

FIG. 6 is a schematic diagram of an exemplary embodiment of a test method. The test method is applied to a test structure. After executing a TSV manufacturing procedure, at least one first TSV and at least one second TSV are formed in the test structure.

First, a test signal is provided to the first TSV (step S610). The disclosure does not limit the type of the test signal. In this embodiment, when a test signal is provided to the first TSV, a coupling effect is caused between the first and the second TSVs. In another embodiment, the test signal only comprises an AC component. In another embodiment, the test signal comprises an AC component and a DC component. In other embodiments, if a test signal, which only comprises a DC component, is provided to the first TSV, the DC component cannot be measured from the second TSV.

The signal of at least one of the first and the second TSVs is measured to obtain a test result (step S630). In one embodiment, a S-parameter impedance, a Y-parameter impedance or a Z-parameter impedance of at least one of the first and the second TSVs is measured to obtain the test result.

An impedance characteristic of an equivalent RLC of the first and the second TSVs is obtained according to the test result (step S650). In one embodiment, the impedance characteristic of the equivalent RLC can be obtained according to the S-parameter impedance, the Y-parameter impedance or the Z-parameter impedance.

In this embodiment, it can be determined whether the TSV procedure is normal according to the variation amount of the coupling effect and the variation amount of the impedance characteristic of the equivalent RLC. Before thinning the wafer, the TSVs are measured. If the TSVs are abnormal, the following procedures (e.g. package procedures) are not implemented and manufacturing costs are reduced.

While the disclosure has been described by way of example and in terms of the embodiments, it is to be understood that the disclosure is not limited to the disclosed embodiments. To the contrary, it is intended to cover various modifications and similar arrangements (as would be apparent to those skilled in the art). Therefore, the scope of the appended claims should be accorded the broadest interpretation to encompass all such modifications and similar arrangements.

What is claimed is:

1. A test structure, comprising:
at least one ground pad receiving a ground signal during a test mode;
an input pad receiving a test signal during the test mode;
at least one first through-silicon via (TSV) coupled to the input pad;
at least one second TSV; and
an output pad coupled to the second TSV,
wherein no connection line occurs between the first and the second TSVs, and
wherein during the test mode, a test result is obtained according to the signal of at least one of the first and the second TSVs, and structural characteristics can be obtained according to the test result.

2. The test structure as claimed in claim 1, wherein when the test structure comprises a plurality of ground pads, the ground pads are divided into a first group and a second group, and a first distance between a first group pad of the first group and the first TSV is shorter than a second distance between the first group pad and the second TSV, and a third distance between a second group pad of the second group and the second TSV is shorter than a fourth distance between the second group pad and the first TSV.

3. The test structure as claimed in claim 1, wherein the test structure comprises a plurality of first TSVs and a plurality of second TSVs, and the first TSVs are electrically connected together via a plurality of first connection lines and the second TSVs are electrically connected together via a plurality of second connection lines.

4. The test structure as claimed in claim 3, wherein the first TSVs and the second TSVs are arranged according to an interdigitated method.

5. The test structure as claimed in claim 3, wherein the distance between one first TSV and one successive first TSV is a first distance, and the distance between one second TSV and one successive second TSV is a second distance and the distance between one first TSV and one second TSV neighboring the first TSV is a third distance.

6. The test structure as claimed in claim 5, wherein the first, the second and the third distances are the same.

7. The test structure as claimed in claim 5, wherein one of the first, the second and the third distances is different from another of the first, the second and the third distances.

8. The test structure as claimed in claim 5, wherein one of the first, the second and the third distances is less than a value, which equals to the diameter of one of the first TSVs and the second TSVs multiplied by 10.

9. The test structure as claimed in claim 1, wherein the shape of one of the first TSVs and the second TSVs is circular or rectangular.

10. The test structure as claimed in claim 1, further comprising:
an internal circuit comprising a plurality of third TSVs, wherein the ground pad, the input pad, the output pad, and the first and the second TSVs are disposed around the internal circuit, and it is obtained whether the third TSV is normal according to the test result.

11. The test structure as claimed in claim 1, wherein when the test signal is provided to the input pad, a coupling effect occurs between the first and the second TSVs.

12. The test structure as claimed in claim 1, wherein the test signal comprises an alternating current (AC) component.

13. The test structure as claimed in claim 12, wherein the test signal further comprises a direct current (DC) component.

14. The test structure as claimed in claim 1, wherein the test structure has not been thinned during the test mode.

15. The test structure as claimed in claim 1, wherein the test structure has been thinned during the test mode.

16. A test method for testing a test structure, wherein when the test structure is produced by a TSV procedure, at least one first TSV and at least one second TSV are formed in the test structure, comprising:
providing a test signal to the first TSV;
measuring the signal of at least one of the first and the second TSVs to obtain a test result; and
obtaining the characteristics of the first and the second TSVs according to the test result, wherein when a DC signal is provided to the first TSV, the DC signal cannot be measured from the second TSV.

17. The test method as claimed in claim 16, wherein when the first TSV receives the test signal, a coupling effect occurs between the first and the second TSVs.

18. The test method as claimed in claim 16, wherein the test signal comprises an AC component.

19. The test method as claimed in claim 16, wherein the test signal further comprises a DC component.

20. The test method as claimed in claim 16, wherein the measuring step is to measure an S-parameter impedance, a Y-parameter impedance or a Z-parameter impedance of at least one of the first and the second TSVs.
